(19) United States
(12) Patent Application Publication
(10) Pub. No.: US 2016/0133788 A1
(43) Pub. Date: May 12, 2016

(54) SEMICONDUCTOR LIGHT-EMITTING DEVICES AND SEMICONDUCTOR LIGHT-EMITTING DEVICE PACKAGES

(71) Applicant: Samsung Electronics Co., Ltd., Suwon-si (KR)

(72) Inventors: Tae Hun KIM, Bucheon-si (KR); Myong Soo CHO, Yongin-si (KR); Yeon Ji KIM, Suwon-si (KR); Yong Seok KIM, Seoul (KR); Tae Kang KIM, Yongin-si (KR); Jae Ho HAN, Hwaseong-si (KR)

(21) Appl. No.: 14/789,278

(22) Filed: Jul. 1, 2015

(30) Foreign Application Priority Data
Nov. 6, 2014 (KR) 10-2014-0153835

(51) Int. Cl. H01L 33/20; H01L 33/38; H01L 33/54; H01L 33/50; H01L 33/46; H01L 33/24; H01L 33/44

(52) U.S. Cl. CPC H01L 33/20; H01L 33/24; H01L 33/38; H01L 33/44; H01L 33/505; H01L 33/46; H01L 33/54

(57) ABSTRACT

Semiconductor light-emitting devices, and semiconductor light-emitting packages, include at least one light-emitting structure including a first conductivity-type semiconductor layer, an active layer, and a second conductivity-type semiconductor layer sequentially stacked on a substrate, the at least one light-emitting structure having a first region and a second region delimiting the first region. The light-emitting device includes a groove in the second region, and the groove is adjacent to an edge of the substrate and extends parallel to the edge of the substrate.

### CROSS-REFERENCE TO RELATED APPLICATION

This application claims priority to and benefit of, under 35 U.S.C. §119, Korean Patent Application No. 10-2014-0153835 filed on Nov. 6, 2014, in the Korean Intellectual Property Office, the disclosure of which is incorporated herein by reference in its entirety.

### BACKGROUND

1. Field

Example embodiments of the present inventive concepts relate to semiconductor light-emitting devices and semiconductor light-emitting device packages.

2. Related Art

Semiconductor light-emitting devices such as light-emitting diodes (LEDs), devices containing a light-emitting material therein to emit light, may convert energy generated due to the recombination of electrons and electron holes into light to be emitted therefrom. Such LEDs are currently in widespread use in lighting elements, display devices and light sources, and the development thereof has accordingly been accelerated. In particular, research into light-emitting diodes having a flip chip structure capable of securing a larger light-emitting area and a semiconductor light-emitting device package including the same is actively being conducted.

Semiconductor light-emitting device packages including light-emitting diodes having a flip-chip structure may include a light-emitting diode, and a reflective wall and a wavelength conversion film enclosing the same. In a manufacturing process, the reflective wall may be formed by applying a liquid having fluidity to a side surface of the light-emitting diode and subsequently, curing the liquid. In a process of forming the reflective wall, defects such as a bleeding phenomenon in which a liquid is introduced into the light-emitting diode may occur.

### SUMMARY

Example embodiments of the present inventive concepts relate to semiconductor light-emitting devices and semiconductor light-emitting device packages.

Example embodiments of the present inventive concepts may be provided to prevent, or reduce, defects that may occur during a process of forming a reflective wall, in a process of manufacturing a semiconductor light-emitting device package.

According to some example embodiments of the present inventive concepts, a semiconductor light-emitting device may include at least one light-emitting structure including a first conductivity-type semiconductor layer, an active layer, and a second conductivity-type semiconductor layer sequentially stacked on a substrate, the at least one light-emitting structure having a first region and a second region enclosing (or delimiting) the first region. The light-emitting device includes a groove in the second region, and the groove is adjacent to an edge of the substrate and extends parallel to the edge of the substrate.

The at least one light-emitting structure may include a mesa region and an etched region having a thickness smaller than a thickness of the mesa region, and the semiconductor light-emitting device may further include a first contact electrode on the first conductivity-type semiconductor layer in the etched region, and a second contact electrode on the second conductivity-type semiconductor layer in the mesa region.

The first contact electrode may extend in a first direction, and the groove may extend in a second direction intersecting the first direction, the groove being in the second region so as to be adjacent to the first contact electrode.

A depth of the groove may be substantially the same depth as a depth of the etched region.

The semiconductor light-emitting device may further include a first insulating layer on the at least one light-emitting structure, the first insulating layer having a first opening exposing at least a portion of the first conductivity-type semiconductor layer and the second conductivity-type semiconductor layer, and a second insulating layer on the first insulating layer, the second insulating layer exposing at least a portion of the first contact electrode and the second contact electrode.

At least one of the first insulating layer and the second insulating layer may be on the groove.

The semiconductor light-emitting device may further include a first metal layer electrically connected to the first contact electrode, and a second metal layer electrically connected to the second contact electrode.

A width of the groove may narrow towards the substrate. A width of the groove may increase towards the substrate.

The semiconductor light-emitting device may further include a hydrophobic insulating layer on at least a portion of the second region. The hydrophobic insulating layer may contain at least one of ZrO₂ and SiN.

According to example embodiments of the present inventive concepts, a semiconductor light-emitting device package includes a semiconductor light-emitting device including a first conductivity-type semiconductor layer, an active layer, and a second conductivity-type semiconductor layer sequentially stacked on a first surface of a substrate, the semiconductor light-emitting device having a first region and a second region having a thickness smaller than a thickness of the first region, a wavelength conversion film attached to a second surface of the substrate opposing the first surface, the wavelength conversion film containing a wavelength conversion material, and a reflective wall delimiting side surfaces of the semiconductor light-emitting device, wherein the semiconductor light-emitting device has a groove adjacent to the reflective wall.

The semiconductor light-emitting device package may further include a hydrophobic insulating layer on at least a portion of the second region.

The reflective wall may contain at least one of TiO₂, SiO₂ and Al₂O₃.

The semiconductor light-emitting device package may further include a package substrate on which the semiconductor light-emitting device is mounted, and an encapsulant between the package substrate, the semiconductor light-emitting device, and the reflective wall.

According to example embodiments, a semiconductor light-emitting device includes a substrate including a first region, and a second region along a periphery of the first region; and at least one light-emitting structure including a semiconductor layer, wherein the semiconductor layer extends over the first region and at least a portion of the second region, and the semiconductor layer has a first groove over the at least a portion of the second region.

A first sidewall and a second sidewall of the semiconductor layer form sides of the first groove, and the first sidewall may slope away from the second sidewall towards a bottom surface of the first groove.

The semiconductor layer includes a second groove over the first region, and bottom surfaces of the first and second grooves may be at a same level.

The semiconductor light-emitting device may further include a hydrophobic insulating layer covering at least a portion of the semiconductor layer extending over the at least a portion of the second region.

The semiconductor layer includes a second groove over the first region, a bottom surface of the second groove may be at a same level as a first bottom surface of the first groove, and the first groove may include a second bottom surface lower than the first bottom surface.

### BRIEF DESCRIPTION OF DRAWINGS

Example embodiments will be more clearly understood from the following detailed description taken in conjunction with the accompanying drawings. FIGS. 1-14 represent non-limiting, example embodiments as described herein.

FIG. 1 is a cross-sectional view of a semiconductor light-emitting device package according to example embodiments of the present inventive concepts;

FIG. 2 is a cross-sectional view of a semiconductor light-emitting device employable in the semiconductor light-emitting device package of FIG. 1;

FIG. 3 is a plan view of a semiconductor light-emitting device according to example embodiments of the present inventive concepts;

FIGS. 4A and 4B are cross-sectional views of the semiconductor light-emitting device of FIG. 3;

FIGS. 5 through 8 are cross-sectional views of semiconductor light-emitting devices according to various example embodiments of the present inventive concepts;

FIGS. 9A through 9E are views illustrating a method of manufacturing a semiconductor light-emitting device according to example embodiments of the present inventive concepts;

FIGS. 10A through 10E are views illustrating a method of manufacturing a semiconductor light-emitting device package according to example embodiments of the present inventive concepts;

FIGS. 11 and 12 are cross-sectional views each illustrating an example of applying the semiconductor light-emitting device package according to example embodiments of the present inventive concepts to a backlight unit;

FIG. 13 is a view illustrating an example of applying the semiconductor light-emitting device package according to example embodiments of the present inventive concepts to a lighting device; and

FIG. 14 is a view illustrating an example of applying the semiconductor light-emitting device package according to example embodiments of the present disclosure to a headlamp.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being ibe various elements, these elements should not be limited by these terms. These terms are only used to di or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms n is for the purpose of describing particular embodiments only and is not intended to be limiting of example embodiments. As used herein, the singular forms “a,” “an” and “the” are intended to include the plural ion of one or more other features, integers, steps, operations, elements, components and/or groups thereof.

Spatially relative terms (e.g., or addition of one or more other features, integers, steps, operations, elements, components and/or groups thereof. As used herein, the singular forms “a,” “an” and “the” are intended tfeature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various features will be described in detail with reference to the attached drawings. However, example embodiments described are not limited thereto.

Example embodiments of the present inventive concepts relate to semiconductor light-emitting devices and semiconductor light-emitting device packages.

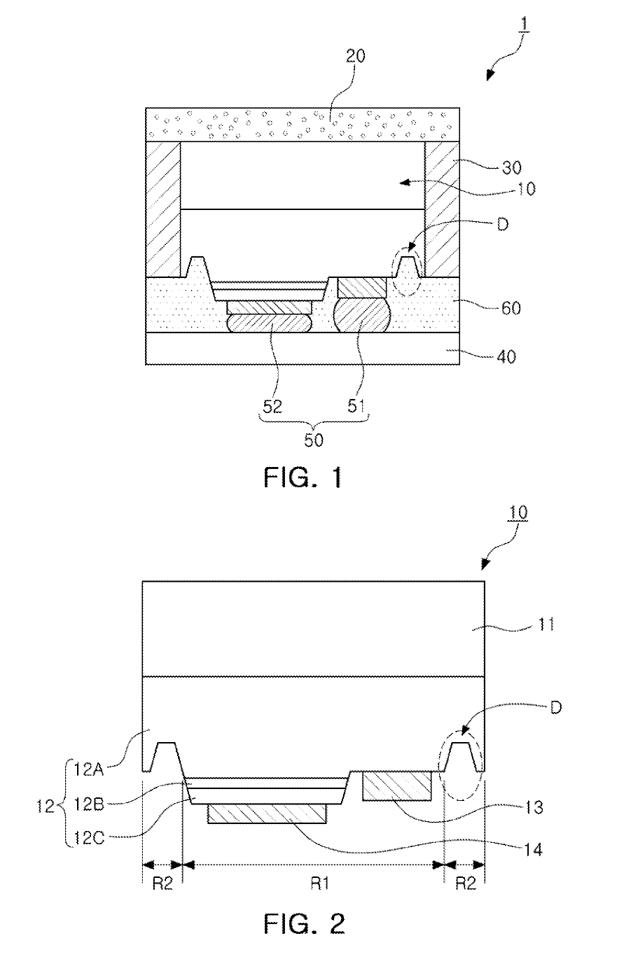

FIG. 1 is a cross-sectional view of a semiconductor light-emitting device package according to example embodiments of the present inventive concepts.

Referring to FIG. 1, a semiconductor light-emitting device package 1 according to example embodiments of the present inventive concepts may include a semiconductor light-emitting device 10, a wavelength conversion film 20, a reflective wall 30, a package substrate 40, and the like. The semiconductor light-emitting device 10 may include a light-emitting structure provided on a substrate, electrodes connected to different conductivity-type semiconductor layers included in the light-emitting structure, and the like.

The semiconductor light-emitting device 10 may be mounted on the package substrate 40 through solder bumps 50 (51 and 52) attached to the respective electrodes, and an encapsulant 60 may be provided in a space between the package substrate 40, the semiconductor light-emitting device 10 and the reflective wall 30. The encapsulant 60 may contain a powder having a high degree of reflectivity such that light generated by the semiconductor light-emitting device 10 may be reflected to be emitted toward the wavelength conversion film 20 on an upper portion of the semiconductor light-emitting device package 1.

Hereinafter, the semiconductor light-emitting device 10 will be described in detail with reference to FIG. 2.

FIG. 2 is a cross-sectional view of the semiconductor light-emitting device employable in the semiconductor light-emitting device package of FIG. 1.

Referring to FIG. 2, the semiconductor light-emitting device 10 according to example embodiments of the present inventive concepts may include a substrate 11, a light-emitting structure 12 including a first conductivity-type semiconductor layer 12A, an active layer 12B, and a second conductivity-type semiconductor layer 12C sequentially stacked on the substrate 11, a first electrode 13 electrically connected to the first conductivity-type semiconductor layer 12A, a second electrode 14 electrically connected to the second conductivity-type semiconductor layer 12C and the like.

The semiconductor light-emitting device 10 according to example embodiments of FIG. 2 may have a flip-chip structure emitting light through the substrate 11. As illustrated in FIG. 1, the first electrode 13 and the second electrode 14 may be attached to the package substrate 40 through the solder bumps 50 or the like. In the active layer 12B, the recombination of electrons and holes may be generated by an electrical signal applied to the package substrate 40. Light generated due to the recombination of electrons and holes may be directly emitted upwardly through the substrate 11, or may be reflected by the first and second electrodes 13 and 14, the reflective wall 30 and the encapsulant 60, and then be upwardly emitted. Thus, the reflective wall 30 may contain at least one of TiO₂, Al₂O₃, and SiO₂, having excellent reflectivity, and the encapsulant 60 may also contain a reflective powder for increasing a degree of reflectivity.

In example embodiments, the first conductivity-type semiconductor layer 12A may be an n-type nitride semiconductor layer, and the second conductivity-type semiconductor layer 12C may be a p-type nitride semiconductor layer. Due to characteristics of the p-type nitride semiconductor layer in which a resistance level thereof is higher than that of the n-type nitride semiconductor layer, because ohmic contact between the second conductivity-type semiconductor layer 12C and the second electrode 14 may be difficult, the second electrode 14 may have a surface area greater than that of the first electrode 13.

The first conductivity-type semiconductor layer 12A and the second conductivity-type semiconductor layer 12C included in the light-emitting structure 12 may be an n-type semiconductor layer and a p-type semiconductor layer, as described above. By way of example, the first conductivity-type semiconductor layer 12A and the second conductivity-type semiconductor layer 12C may be formed of a group III nitride semiconductor, for example, a material having a composition of AlₓIn_{y}Ga_{1-x-y}N (0≦x≦1, 0≦y≦1, 0≦x+y≦1). The materials of the first conductivity-type semiconductor layer 12A and the second conductivity-type semiconductor layer 12C are not limited thereto, and may be an AlGaInP based semiconductor or an AlGaAs based semiconductor.

Meanwhile, the first and second conductivity-type semiconductor layers 12A and 12C may have a single layer structure, or may have a multi-layer structure in which respective layers have different compositions, thicknesses or the like. For example, each of the first and second conductivity-type semiconductor layers 12A and 12C may include a carrier injection layer for improving injection efficiency of electrons and holes and further, may have a superlattice structure formed in various manners.

The first conductivity-type semiconductor layer 12A may further include a current spreading layer in a portion thereof adjacent to the active layer 12B. The current spreading layer may have a structure in which a plurality of InₓAl_{y}Ga_{(1-x-y)}N layers having different compositions, or different impurity contents, are repeatedly stacked or may be partially formed of an insulating material layer.

The second conductivity-type semiconductor layer 12C may further include an electron blocking layer in a portion thereof adjacent to the active layer 12B. The electron blocking layer may have a structure in which a plurality of InₓAl_{y}Ga_{(1-x-y)}N layers, wherein 0≦x≦1, 0≦y≦1, 0≦x+y≦1, having different compositions are stacked or may have at least one layer configured of Al_{y}Ga_{(1-y)}N, wherein 0≦y≦1. The second conductivity-type semiconductor layer 12C may have a band gap greater than that of the active layer 12B to prevent electrons from passing over the second conductivity-type semiconductor layer 12C.

The light-emitting structure 12 may be formed using an MOCVD device. In order to manufacture the light-emitting structure 12, an organic metal compound gas (for example, trimethylgallium (TMG), trimethyl aluminum (TMA) and the like) and a nitrogen-containing gas (ammonia (NH₃) and the like) are supplied as a reaction gas, to a reaction container in which a growth substrate is installed, and a temperature of the substrate is maintained at a high temperature of approximately (or about) 900° C. to 1100° C., such that gallium nitride compound semiconductors may be grown on the substrate while supplying an impurity gas thereto if necessary, to thereby allow the gallium nitride compound semiconductors to be stacked as an undoped layer, an n-type layer, and a p-type layer, on the substrate. An n-type impurity may be Si, or other materials widely known in the art, and a p-type impurity may be Zn, Cd, Be, Mg, Ca, Ba or the like. As the p-type impurity, Mg and Zn may be preferable.

In addition, the active layer 12B interposed between the first and second conductivity-type semiconductor layers 12A and 12C may have a multiple quantum well (MQW) structure in which quantum well layers and quantum barrier layers are alternately stacked. For example, in the case that the active layer 12B includes a nitride semiconductor, the active layer 12B may have a multiple quantum well (MQW) structure in which GaN and InGaN are alternately stacked. Depending on example embodiments, the active layer 12B may have a single quantum well (SQW) structure.

Referring to FIG. 2, the semiconductor light-emitting device 10 according to example embodiments of the present inventive concepts may include a first region R1 and a second region R2 enclosing the first region R1. The first electrode 13 and the second electrode 14 may be positioned in the first region R1, and the first region R1 may be a light-emitting region in which light may be generated due to the recombination of electrons and holes in the active layer 12B included therein. In a plane of the semiconductor light-emitting device 10, the first region R1 may be enclosed (or, alternatively, delimited) by the second region R2. A groove D having a ditch (or trapezoidal) shape may be formed in the second region R2.

As illustrated in FIGS. 1 and 2, the groove D may have a ditch shape in which it extends along an edge of the semiconductor light-emitting device 10 in a direction parallel thereto within the second region R2. In a process of manufacturing the semiconductor light-emitting device package 1, after disposing the semiconductor light-emitting device 10 on the wavelength conversion film 20, the reflective wall 30 may be formed on the side surface of the semiconductor light-emitting device 10. The reflective wall 30 may be formed by providing a TiO₂ paste and the like, that have fluidity to a height identical to that of the side surface of the semiconductor light-emitting device 10, and curing the paste. In this case, when the height of the TiO₂ paste is greater than that of the side surface of the semiconductor light-emitting device 10, a bleeding phenomenon in which the TiO₂ paste penetrates into the semiconductor light-emitting device 10 may occur.

In example embodiments of the present inventive concepts, due to the groove D provided in the second region R2 of the semiconductor light-emitting device 10, such a bleeding phenomenon may be prevented. In order words, even in the case that the height of the TiO₂ paste is greater than that of the side surface of the semiconductor light-emitting device 10, because a spare amount of the TiO₂ paste may flow into the groove D, a phenomenon in which the TiO₂ paste penetrates into the semiconductor light-emitting device 10 may be prevented.

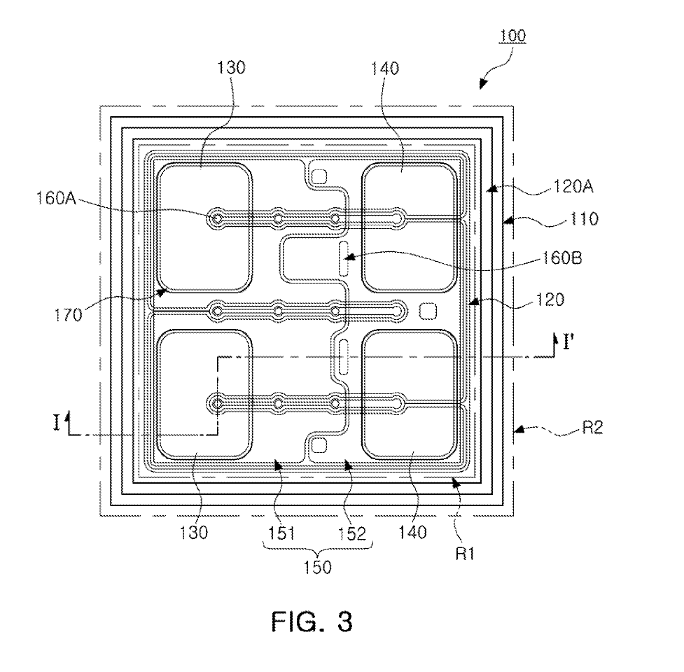

FIG. 3 is a plan view of a semiconductor light-emitting device according to example embodiments of the present inventive concepts.

Referring to FIG. 3, a semiconductor light-emitting device 100 according to example embodiments of the present inventive concepts may include a first region R1, and a second region R2 enclosing the first region R1. A groove 120A having a ditch shape may be formed in the second region R2. The groove 120A may have a shape in which it extends in a direction parallel to an edge of a substrate 110 to enclose the first region R1. FIG. 3 illustrates a case in which the groove 120A may be formed over the entirety of the second region R2 to enclose the overall first region R1. Alternatively, the groove 120A may be formed in only a portion of the second region R2. In a similar manner to the semiconductor light-emitting device 10 illustrated in FIG. 2, a light-emitting structure 120 may be formed on the substrate 110. The light-emitting structure 120 may include a first conductivity-type semiconductor layer, an active layer, and a second conductivity-type semiconductor layer sequentially stacked from the substrate 110.

As described above with reference to FIG. 1, the semiconductor light-emitting device 100 may be mounted on a package substrate in a flip chip scheme. Thus, as illustrated in FIG. 3, the semiconductor light-emitting device 100 may include the first and second electrodes 130 and 140. The first and second electrodes 130 and 140 may be formed on open regions formed by removing portions of a cover layer 170. Meanwhile, the amounts and the disposition structure of the first and second electrodes 130 and 140 are not limited to the drawings and may be variously changed. In addition, in example embodiments, the first and second electrodes 130 and 140 may be, for example, under bump metallurgy (UBM) layers.

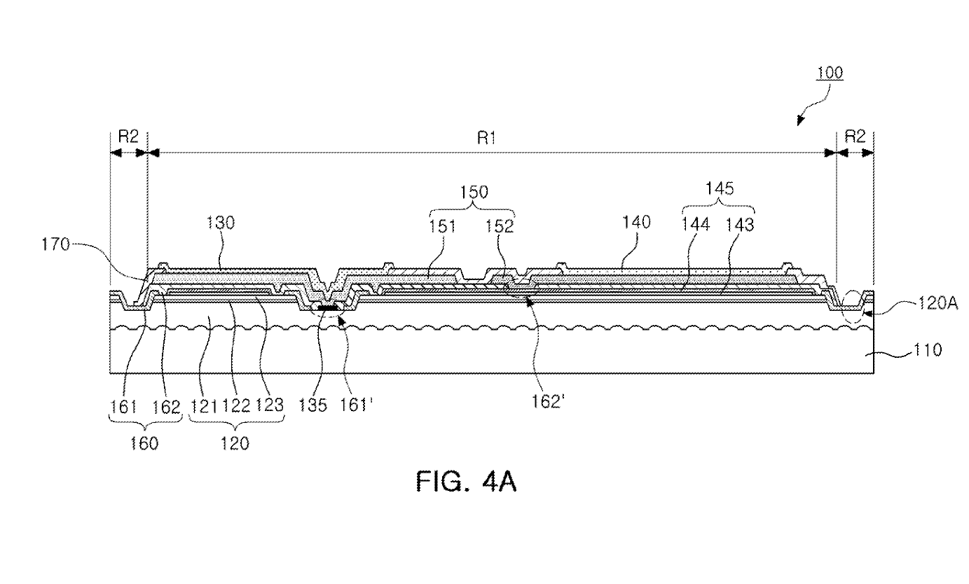

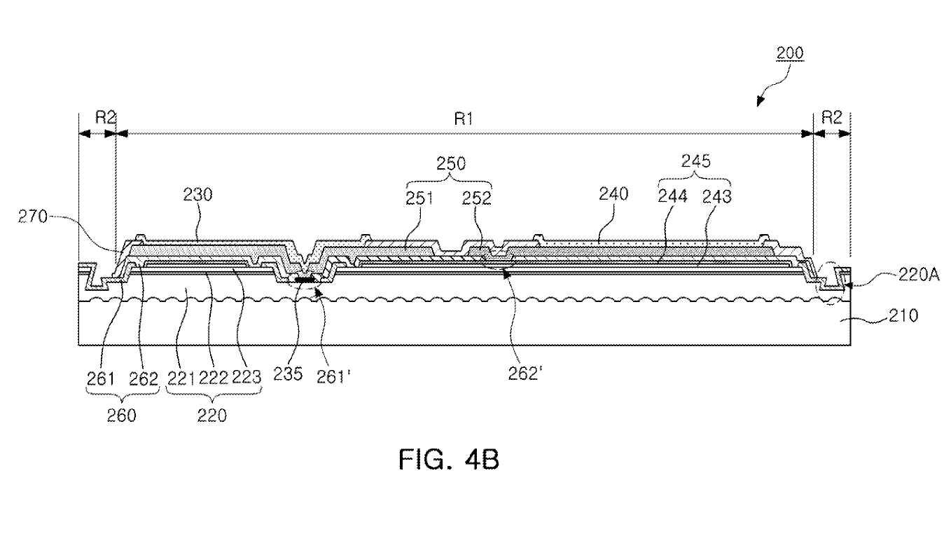

The first electrode 130 and the second electrode 140 may be provided on first and second metal layers 151 and 152. The first metal layer 151 may be electrically connected to a first contact electrode provided on the first conductivity-type semiconductor layer through a first opening 161′ (shown in FIG. 4A), and the second metal layer 152 may be electrically connected to a second contact electrode provided on the second conductivity-type semiconductor layer through a second opening 162′ (shown in FIG. 4A).

Hereinafter, the semiconductor light-emitting device of FIG. 3 will be described in detail with reference to FIGS. 4A and 4B.

FIGS. 4A and 4B are cross-sectional views of the semiconductor light-emitting device of FIG. 3.

Referring to FIG. 4A, first, the semiconductor light-emitting device 100 according to example embodiments of the present inventive concepts may include the substrate 110, the light-emitting structure 120 disposed on the substrate 110, the first electrode 130 and the second electrode 140, and the like. The light-emitting structure 120 may include a first conductivity-type semiconductor layer 121, an active layer 122, and a second conductivity-type semiconductor layer 123 sequentially stacked from the substrate 110.

The substrate 110 may be, for example, a sapphire substrate, and may be provided as a semiconductor growth substrate. In the case that the substrate 110 is a sapphire substrate, the substrate 110 may be a crystal having electrical insulating properties and Hexa-Rhombo R3c symmetry. The sapphire substrate 110 may have a lattice constant of 13.001 Å in a C-axial direction and a lattice constant of 4.758 Å in an A-axial direction and may include a C (0001) plane, an A (1120) plane, an R (1102) plane, and the like. In this case, the C plane is mainly used as a nitride growth substrate for forming the light-emitting structure 120 because the C plane facilitates the growth of a nitride film and is stable at high temperature. A plurality of unevenness structures may be formed on an upper surface of the substrate 110, that is, a surface on which the light-emitting structure 120 is formed.

Meanwhile, a buffer layer (not shown) may be further provided on an upper surface of the substrate 110. The buffer layer may be provided to alleviate lattice defects of the semiconductor layers grown on the substrate 110 and may be formed of an undoped semiconductor layer formed of a nitride or the like. The buffer layer may alleviate a difference in lattice constants between the substrate 110 formed of sapphire and the first conductivity-type semiconductor layer 121 formed of GaN and stacked on the upper surface of the substrate 110 to thereby enhance crystallinity of a GaN layer. The buffer layer may be formed using undoped GaN, AIN, InGaN and the like and may be grown to have a thickness of several tens to several hundred A at a low temperature of 500° C. to 600° C. Here, the term “an undoped state” means that a separate impurity doping process is not performed on the semiconductor layer and in this case, an inherent impurity concentration in the semiconductor layer may be contained. For example, in the case that a gallium nitride semiconductor is grown using metal organic chemical vapor deposition (MOCVD), Si and the like used as a dopant may be contained in an amount of approximately 1104 cm³ to 1108/cm³, even though it is not intended. However, the buffer layer may be omitted depending on example embodiments.

As described above, the light-emitting structure 120 may include the first conductivity-type semiconductor layer 121, the active layer 122, and the second conductivity-type semiconductor layer 123. The first conductivity-type semiconductor layer 121 may be formed of a semiconductor doped with an n-type impurity, and may be an n-type nitride semiconductor layer. The second conductivity-type semiconductor layer 123 may be formed of a semiconductor doped with a p-type impurity, and may be a p-type nitride semiconductor layer. However, according to example embodiments, the first and second conductivity-type semiconductor layers 121 and 123 may be stacked by switching positions thereof. The first and second conductivity-type semiconductor layers 121 and 123 may have a compositional formula of AlₓIn_{y}Ga_{(1-x-y)}N (where, 0≦x≦1, 0≦y≦1, 0≦x+y≦1) and materials having such a compositional formula may be, for example, GaN, AlGaN, InGaN, AlInGaN and the like.

The active layer 122 interposed between the first and second conductivity-type semiconductor layers 121 and 123 may emit light having set (or predetermined) energy due to the recombination of electrons and holes. The active layer 122 may contain a material having an energy band gap smaller than those of the first and second conductivity-type semiconductor layers 121 and 123. For example, in the case that the first and second conductivity-type semiconductor layers 121 and 123 are GaN-based compound semiconductors, the active layer 122 may contain an InGaN-based compound semiconductor having an energy band gap smaller than that of GaN. In addition, the active layer 122 may have a multiple quantum well (MQW) structure in which quantum well and quantum barrier layers are alternately stacked, for example, a structure of InGaN/GaN. However, because the structure of the active layer 122 is not limited thereto, the active layer 122 may also have a single-quantum well (SQW) structure.

In a manufacturing process, after forming the light-emitting structure 120 on the substrate 110, a mesa region and an etched region may be formed by removing at least partial regions of the light-emitting structure 120. In particular, in the example embodiments of the present inventive concepts, in a process of forming the mesa region and the etched region, the groove 120A may be formed by selectively removing a portion of the light-emitting structure 120 within the second region R2 adjacent to the edge of the substrate 110. As illustrated in FIG. 4A, the groove 120A may be extended in the direction parallel to the edge of the substrate 110 or the light-emitting structure 120 within the second region R2. Meanwhile, because the groove 120A may be simultaneously formed in the process of forming the mesa region and the etched region, the groove 120A may have substantially the same depth as that of the etched region. That is, an upper surface of the etched region and an inside bottom surface of the groove 120A may form a coplanar surface.

A first contact electrode 135 and a second contact electrode 145 may be formed on the first conductivity-type semiconductor layer 121 and the second conductivity-type semiconductor layer 123, respectively. The first contact electrode 135 may be disposed on the first conductivity-type semiconductor layer 121 in the etched region, and the second contact electrode 145 may be disposed on the second conductivity-type semiconductor layer 123 in the mesa region. The first contact electrode 135 may have pad portions and finger portions having widths narrower than those of the pad portions as illustrated in FIG. 3, in order to implement a uniform injection in the electrode. The pad portions may be spaced apart from each other, and the finger portions may connect the pad portions to each other.

The second contact electrode 145 may include a reflective metal layer 143 and a coating metal layer 144 covering the reflective metal layer 143. The coating metal layer 144 may be selectively provided and may be omitted according to example embodiments. The second contact electrode 145 may be provided to cover an upper surface of the second conductivity-type semiconductor layer 123. That is, the second contact electrode 145 may have a surface area larger than that of the first contact electrode 135 in consideration of characteristics of the second conductivity-type semiconductor layer 123 having a relatively high degree of electrical resistance and as illustrated in FIG. 3, may include a plurality of layers. The first contact electrode 135 and the second contact electrode 145 may be formed on regions prepared by selectively removing a first insulating layer 161 formed on the light-emitting structure 120.

A second insulating layer 162 may be prepared on the first contact electrode 135 and the second contact electrode 145. The second insulating layer 162 may expose at least a portion of each of the first contact electrode 135 and the second contact electrode 145. At least portions of an insulating layer 160 (161-162) may be removed as described above, such that the first opening 161′ and the second opening 162′ may be respectively provided in the first contact electrode 135 and the second contact electrode 145 as illustrated in FIG. 4A. Meanwhile, the insulating layer 160 may contain silicon oxide or silicon nitride, for example, SiO₂, SiN, SiOₓN_{y}, TiO₂, Si₃N₄, Al₂O₃, TiN, AIN, ZrO₂, TiAlN, TiSiN or the like.

A metal layer 150 may be provided on the insulating layer 160. The metal layer 150 may include a first metal layer 151 and a second metal layer 152. The first contact electrode 135 may be connected to the first metal layer 151 through the first opening 161′, and the second contact electrode 145 may be connected to the second metal layer 152 through the second opening 162′. The metal layer 150 may be formed of, for example, a material containing one or more among materials such as Au, W, Pt, Si, Ir, Ag, Cu, Ni, Ti, Cr and the like and alloys thereof.

The cover layer 170 formed of an insulating material may be further provided on the metal layer 150. The cover layer 170 may cover side surfaces of the light-emitting structure 120 and the metal layer 150. Partial regions of the cover layer 170 may be selectively removed, and the first electrode 130 and the second electrode 140 may be prepared on the regions from which portions of the cover layer 170 are removed. That is, as illustrated in FIG. 4A, the first electrode 130 may be disposed on the first metal layer 151, and the second electrode 140 may be disposed on the second metal layer 152. Consequently, the first electrode 130 may be electrically connected to the first conductivity-type semiconductor layer 121 through the first metal layer 151 and the first contact electrode 135, and the second electrode 140 may be electrically connected to the second conductivity-type semiconductor layer 123 through the second metal layer 152 and the second contact electrode 145.

Meanwhile, as described above, the semiconductor light-emitting device 100 according to the example embodiments of the present inventive concepts may have the groove 120A provided to be adjacent to an edge of the semiconductor light-emitting device 100. The groove 120A may be formed by selectively retaining at least a portion of the light-emitting structure 120 adjacent to the edge of the semiconductor light-emitting device 100 in a process of selectively etching the light-emitting structure 120 and forming the mesa region.

In a manufacturing process of a semiconductor light-emitting device package, after a plurality of semiconductor light-emitting devices 100 are disposed on a fluorescent film, resin containing a filler such as TiO₂ or the like may be injected into a space between the semiconductor light-emitting devices 100, using a dispenser. The resin may be cured to manufacture a reflective wall. At this moment, if the amount of resin injected to manufacture the reflective wall is not appropriately controlled, then a bleeding phenomenon in which resin is introduced to the edge of the semiconductor light-emitting device 100, a region in which the first contact electrode 135 is provided or the like, may occur.

In example embodiments of the present inventive concepts, the groove 120A may be formed to be adjacent to the edge of the semiconductor light-emitting device 100, such that the introduction of resin for forming the reflective wall may be prevented. Even in the case that an excessive amount of resin for forming the reflective wall is injected, only the groove 120A may be filled with the resin but the resin may not be introduced to an upper surface of the semiconductor light-emitting device 100. Thus, the bleeding phenomenon may be prevented.

Referring to FIG. 3, the first contact electrode 135 may be extended in a first axial direction—a horizontal direction of FIG. 3 by the pad portions and the finger portions thereof. Because the first contact electrode 135 may be provided in the etched region (a region thinner than the mesa region), resin for forming the reflective wall may be introduced into the etched region in which the first contact electrode 135 is formed. In order to prevent the introduction of resin, the groove 120A may be extended in a second axial direction intersecting a length direction (first axial direction) of the first contact electrode 135 and may be disposed within the second region R2 between the edge of the substrate 110 and the first contact electrode 135.

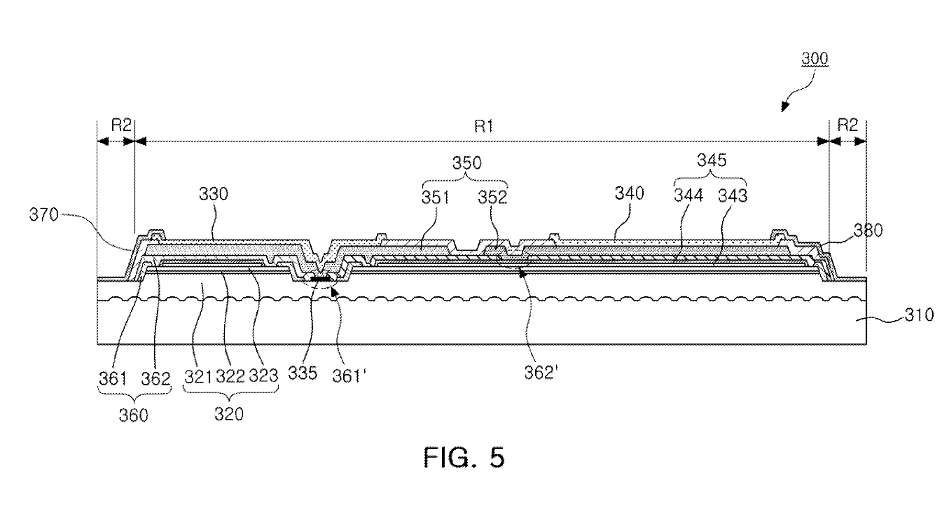

Meanwhile, the cover layer 170 may be disposed on a portion of an inside of the groove 120A. The cover layer 170 may be formed of an insulating material containing SiO₂, SiN, SiOₓN_{y}, TiO₂, Si₃N₄, Al₂O₃, TiN, AIN, ZrO₂, TiAlN, TiSiN or the like. In particular, in the case that the cover layer 170 contains TiO₂ or ZrO₂, having hydrophobic characteristics, the cover layer 170 may perform the same functions as those of a hydrophobic insulating layer described to be later with reference to FIG. 5.

Next, referring to FIG. 4B, a semiconductor light-emitting device 200 according to example embodiments of the present inventive concepts may include a substrate 210, a light-emitting structure 220 disposed on the substrate 210, a first electrode 230, a second electrode 240 and the like. Characteristics of a first conductivity-type semiconductor layer 221, an active layer 222, and a second conductivity-type semiconductor layer 223 included in the light-emitting structure 220, an insulating layer 260, contact electrodes 235 and 245, a metal layer 250, a cover layer 270 and the like are similar to those of the semiconductor light-emitting device 100 illustrated in FIG. 4A.

However, the semiconductor light-emitting device 200 according to the example embodiments illustrated in FIG. 4B may be different from the semiconductor light-emitting device 100 according to the foregoing example embodiments illustrated in FIG. 4A in terms of a shape of a groove 220A. In the semiconductor light-emitting device 100 according to the foregoing example embodiments illustrated in FIG. 4A, because the groove 120A may be formed by selectively retaining a portion of the light-emitting structure 120 adjacent to the edge of the semiconductor light-emitting device 100 in the process of selectively etching the light-emitting structure 120 and forming the mesa region, a width of the groove 120A may be narrowed toward the substrate 110.

On the other hand, in the semiconductor light-emitting device 200 according to the example embodiments illustrated in FIG. 4B, the groove 220A may have a width increasing toward the substrate 210. In the example embodiments illustrated in FIG. 4B, the groove 220A may be formed using a separate etching process, rather than a process of removing a portion of the light-emitting structure 220 and forming a mesa region. For example, after preparing the mesa region by forming the light-emitting structure 220 on the substrate 210 and selectively removing a partial region of the light-emitting structure 220 in the first region R1, another partial region of the light-emitting structure 220 in the second region R2 may be selectively removed again to thereby form the groove 220A.

Next, with reference to FIGS. 5 through 8, semiconductor light-emitting devices according to various example embodiments of the present inventive concepts will be described.

Referring to FIG. 5, a semiconductor light-emitting device 300 according to example embodiments of the present inventive concepts may include a substrate 310, a light-emitting structure 320 disposed on the substrate 310, an insulating layer 360 provided on the light-emitting structure 320, contact electrodes 335 and 345, a metal layer 350 and the like. The light-emitting structure 320 may include a first conductivity-type semiconductor layer 321, an active layer 322, a second conductivity-type semiconductor layer 323 and the like. The first conductivity-type semiconductor layer 321 and the second conductivity-type semiconductor layer 323 may be connected to a first contact electrode 335 and a second contact electrode 345, respectively. The second contact electrode 345 may have a surface area relatively larger than that of the first contact electrode 335 and may have a structure in which a reflective metal layer 343 and a coating metal layer 344 are stacked.

A first insulating layer 361 and a second insulating layer 362 may be provided on the light-emitting structure 320. The first contact electrode 335 and the second contact electrode 345 may be disposed on exposed portions of the first conductivity-type semiconductor layer 321 and the second conductivity-type semiconductor layer 323 exposed by removing at least portions of the first insulating layer 361, and the second insulating layer 362 may be provided on the contact electrodes 335 and 345. Partial regions of the second insulating layer 362 may also be selectively removed, similar to the case of the first insulating layer 361, and in regions of the contact electrodes 335 and 345 from which the second insulating layer 362 is removed, the contact electrodes 335 and 345 may be connected to the metal layer 350. Referring to FIG. 5, the first contact electrode 335 may be connected to the first metal layer 351 in a first opening 361′ and the second contact electrode 345 may be connected to the second metal layer 352 in a second opening 362′. A first electrode 330 and a second electrode 340 may be respectively formed on the metal layer 350.

The semiconductor light-emitting device 300 according to the example embodiments illustrated in FIG. 5 may have a first region R1 and a second region R2 enclosing (or delimiting) the first region R1. A hydrophobic insulating layer 380 may be provided in the second region R2. The hydrophobic insulating layer 380 may contain at least one of ZrO₂ and SiN. In a manufacturing process of a package including the semiconductor light-emitting device 300, the hydrophobic insulating layer 380 may prevent resin injected to form a reflective wall on a side surface of the semiconductor light-emitting device 300 from being introduced to the first region R1 of the semiconductor light-emitting device 300.

That is, the hydrophobic insulating layer 380 may perform the same functions as those of the grooves 120A and 220A provided in FIG. 4A or FIG. 4B. FIG. 5 illustrates a case in which the hydrophobic insulating layer 380 is provided on the second region R2 and a portion of the first region R1 adjacent to the second region R2, but the hydrophobic insulating layer 380 is not limited to having such a form. Because the resin injected to form the reflective wall may be easily introduced to the first region R1 through an etched region within the first region R1, the hydrophobic insulating layer 380 may be provided on the etched region within the first region R1, that is, on a region in which the first contact electrode 335 is disposed.

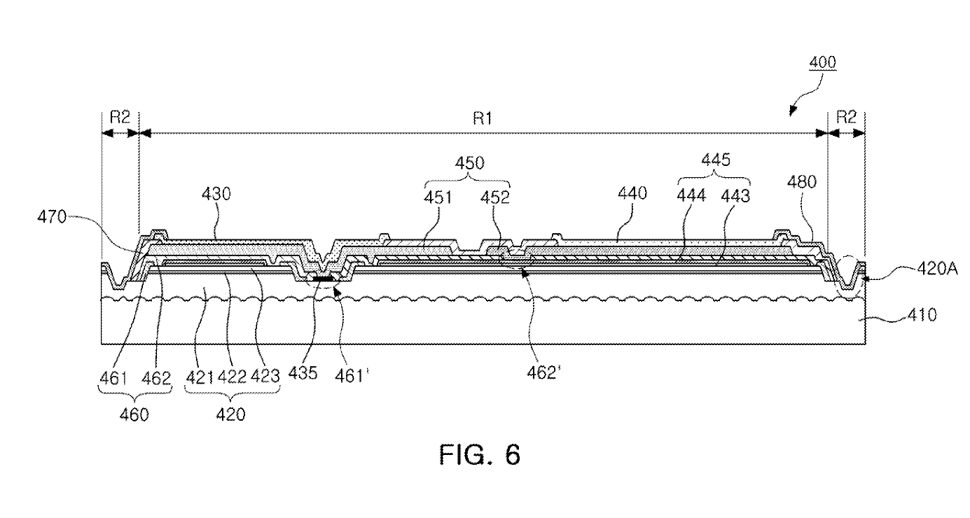

Next, referring to FIG. 6, a semiconductor light-emitting device 400 according to example embodiments of the present inventive concepts may include a substrate 410, a light-emitting structure 420 disposed on the substrate 410, an insulating layer 460 provided on the light-emitting structure 420, contact electrodes 435 and 445, a metal layer 450 and the like. The light-emitting structure 420 may include a first conductivity-type semiconductor layer 421, an active layer 422, and a second conductivity-type semiconductor layer 423. The first conductivity-type semiconductor layer 421 and the second conductivity-type semiconductor layer 423 may be connected to a first contact electrode 435 and a second contact electrode 445, respectively. The first contact electrode 435 may be connected to a first metal layer 451 and a first electrode 430 in a first opening 461′ and the second contact electrode 445 may be connected to a second metal layer 452 and a second electrode 440 in a second opening 462′.

The semiconductor light-emitting device 400 according to the example embodiments illustrated in FIG. 6 may include a hydrophobic insulating layer 480 provided on a second region R2 and a portion of a first region R1 adjacent to the second region R2, in a similar manner to the semiconductor light-emitting device 300 according to the example embodiments illustrated in FIG. 5. The hydrophobic insulating layer 480 may contain at least one of ZrO₂ and SiN. The semiconductor light-emitting device 400 according to the example embodiments illustrated in FIG. 6 may include a groove 420A provided in the second region R2, similarly to the semiconductor light-emitting devices 100 and 200 illustrated in FIGS. 4A and 4B.

In particular, in the semiconductor light-emitting device 400 according to the example embodiments illustrated in FIG. 6, the hydrophobic insulating layer 480 may be disposed on the groove 420A within the second region R2. As illustrated in FIG. 6, the hydrophobic insulating layer 480 may be provided on a side surface and a bottom surface of an interior portion of the groove 420A and may further efficiently prevent resin injected for forming a reflective wall from being introduced to the semiconductor light-emitting device 400. Meanwhile, similar to the description with reference to FIG. 5, the hydrophobic insulating layer 480 may be further provided on an etched region within the first region R1 in which the first contact electrode 435 is disposed.

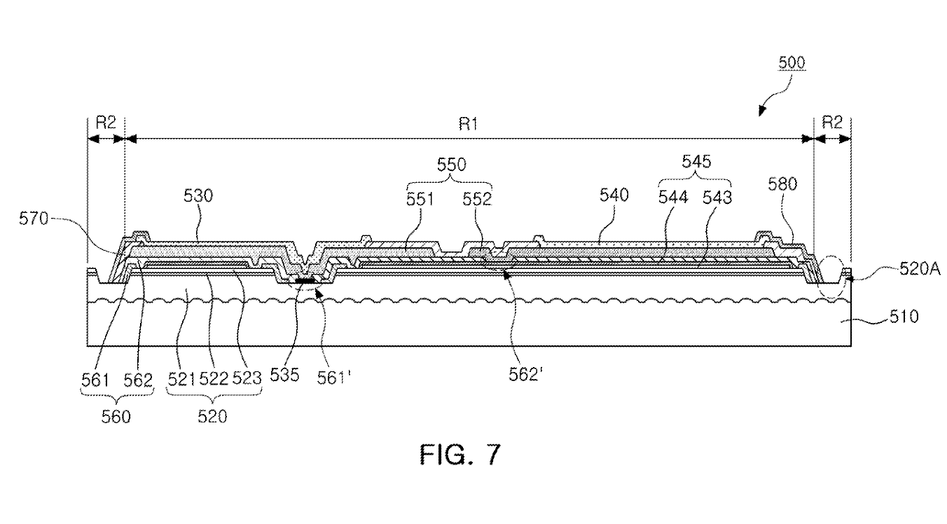

Next, referring to FIG. 7, a semiconductor light-emitting device 500 according to example embodiments illustrated in FIG. 7 may include a substrate 510, a light-emitting structure 520 disposed on the substrate 510 and including a first conductivity-type semiconductor layer 521, an active layer 522, and a second conductivity-type semiconductor layer 523, an insulating layer 560 provided on the light-emitting structure 520, contact electrodes 535 and 545, a metal layer 550 and the like. The first conductivity-type semiconductor layer 521 and the second conductivity-type semiconductor layer 523 may be connected to a first contact electrode 535 and a second contact electrode 545, respectively. The first contact electrode 535 may be connected to a first metal layer 551 and a first electrode 530 in a first opening 561′, and the second contact electrode 545 may be connected to a second metal layer 552 and a second electrode 540 in a second opening 562′.

Referring to FIG. 7, in order to protect the semiconductor light-emitting device 500, a groove 520A and a hydrophobic insulating layer 580 may be provided in a second region R2. A portion of the hydrophobic insulating layer 580 may also be provided in the first region R1 adjacent to the second region R2. In particular, as illustrated in FIG. 7, the groove 520A may be disposed to be closer to an edge of the substrate 510 as compared to the hydrophobic insulating layer 580. Thus, even in the case that resin injected to form a reflective wall in a process of manufacturing a semiconductor light-emitting device package is introduced to the groove 520A, the hydrophobic insulating layer 580 may prevent the resin introduced to the groove 520A from penetrating into the first region R1 of the semiconductor light-emitting device 500.

Unlike the example embodiments of FIG. 6, the groove 520A may be provided closer to the first region R1 as compared to the hydrophobic insulating layer 580, and the hydrophobic insulating layer 580 may be disposed closer to the edge of the substrate 510 as compared to the groove 520A. That is, the hydrophobic insulating layer 580 may be disposed between the edge of the substrate 510 and the groove 520A. In this case, a phenomenon in which resin injected in an excessive amount is introduced to the first region R1 may be primarily blocked and a phenomenon in which resin having passed through the hydrophobic insulating layer 580 is introduced to the first region R1 may be blocked by the groove 520A.

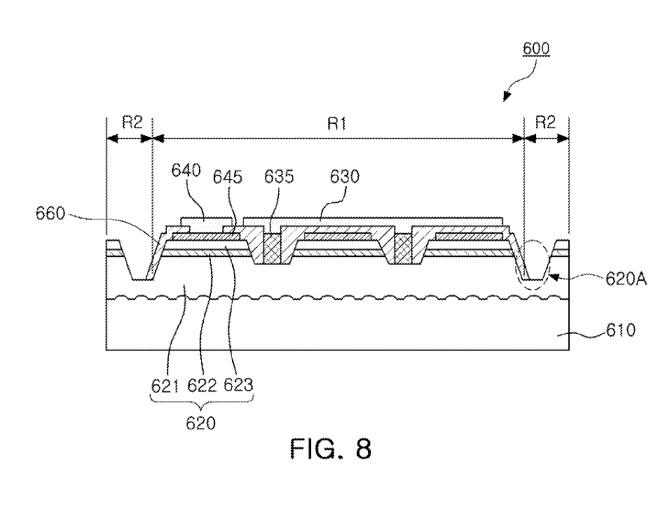

Next, referring to FIG. 8, a semiconductor light-emitting device 600 according to the example embodiments illustrated in FIG. 8 may include a substrate 610, a light-emitting structure 620, contact electrodes 635 and 645, an insulating layer 660, and first and second electrodes 630 and 640 disposed on the substrate 610, and the like. The light-emitting structure 620 may include a first conductivity-type semiconductor layer 621, an active layer 622, a second conductivity-type semiconductor layer 623 and the like. The first conductivity-type semiconductor layer 621 and the second conductivity-type semiconductor layer 623 may be connected to a first contact electrode 635 and a second contact electrode 645, respectively. At least partial regions of the insulating layer 660 provided on the light-emitting structure 620 may be removed and in regions of the light-emitting structure 620 from which the insulating layer 660 is removed, the first electrode 630 and the second electrode 640 may be connected to the first contact electrode 635 and the second contact electrode 645, respectively.

The semiconductor light-emitting device 600 may have a first region R1 and a second region R2 enclosing the first region R1. A groove 620A may be provided in the second region R2. In a manufacturing process of a package including the semiconductor light-emitting device 600, the groove 620A may prevent resin for forming a reflective wall from being introduced to the first region R1 of the semiconductor light-emitting device 600.

In the semiconductor light-emitting devices according to example embodiments of the present inventive concepts, depths of the grooves 120A, 220A, 420A, 520A, and 620A may be variously modified. In FIGS. 4A, 4B, 5, 7 and 8, the grooves 120A, 220A, 420A, 520A, and 620A may have depths sufficient to penetrate through the first conductivity-type semiconductor layer 621. In some example embodiments, the depths of the grooves 120A, 220A, 420A, 520A, and 620A may be identical to a depth of an etched region present within the first region R1. In addition, the depths of the grooves 120A, 220A, 420A, 520A, and 620A may be increased such that the grooves 120A, 220A, 420A, 520A, and 620A may penetrate through the substrate 610. The depths of the grooves 120A, 220A, 420A, 520A, and 620A may be decreased such that the grooves 120A, 220A, 420A, 520A, and 620A may only penetrate through the active layer 622.

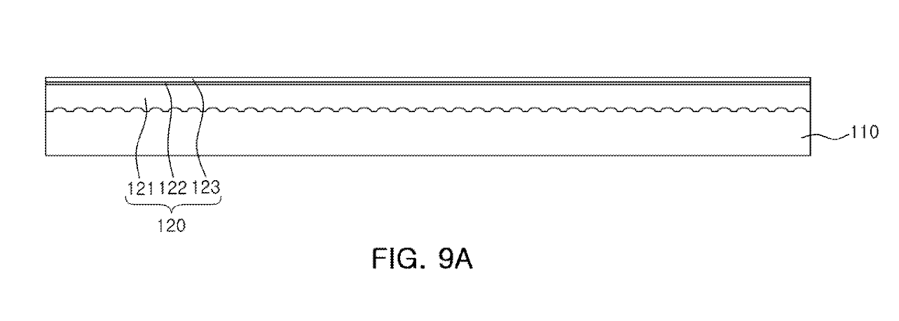

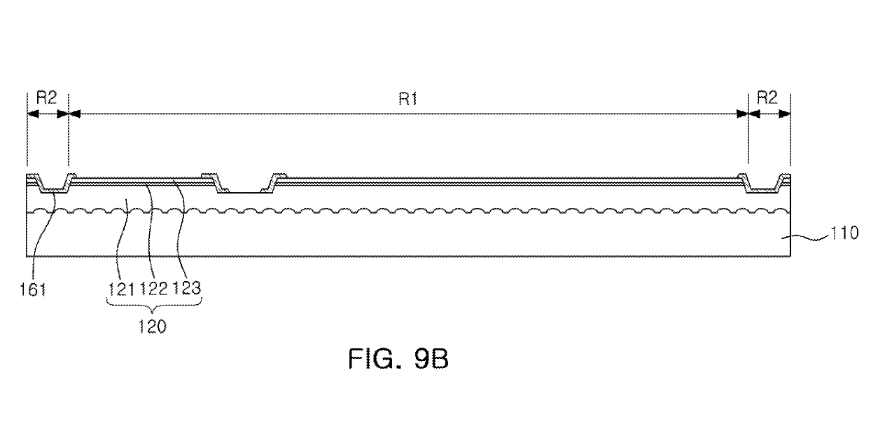

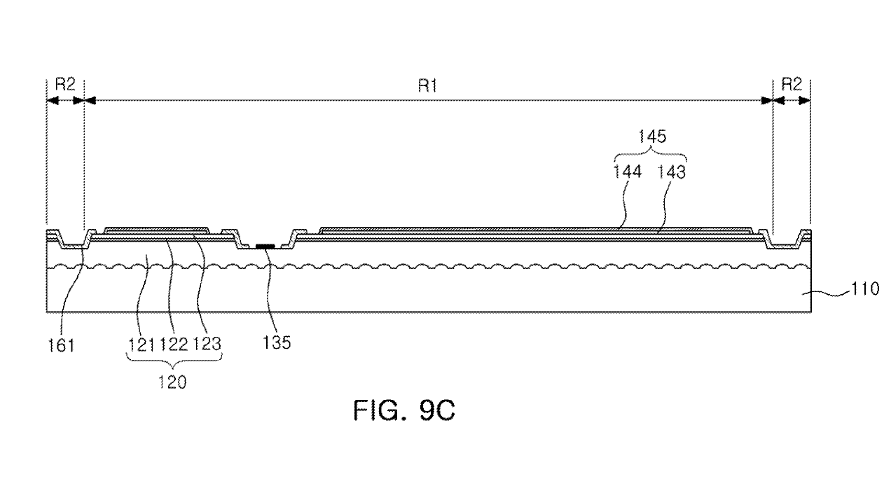

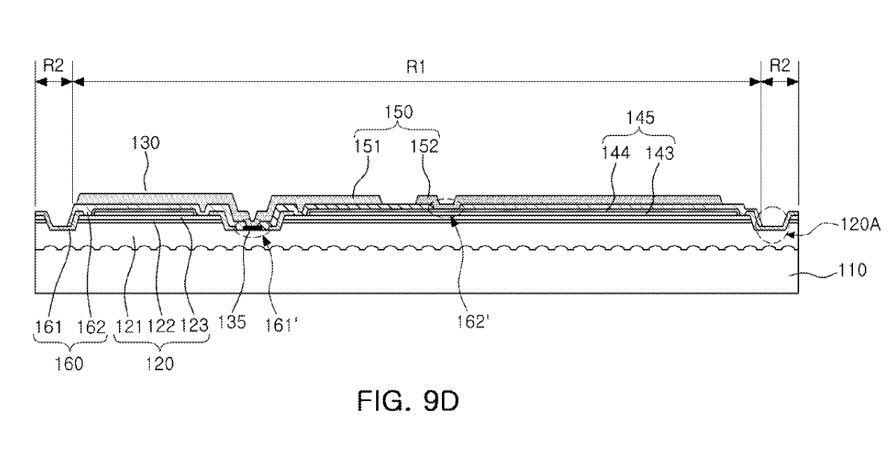

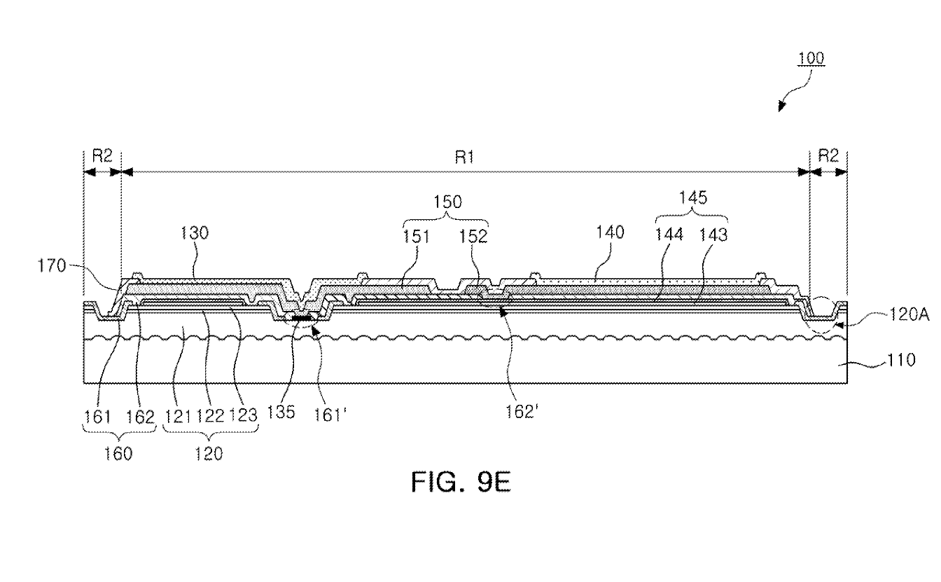

FIGS. 9A through 9E are views illustrating a method of manufacturing a semiconductor light-emitting device according to example embodiments of the present inventive concepts.

Referring to FIG. 9A, the light-emitting structure 120 may be formed on the substrate 110. The light-emitting structure 120 may include the first conductivity-type semiconductor layer 121, the active layer 122, and the second conductivity-type semiconductor layer 123 sequentially stacked from the substrate 110. As illustrated in FIG. 9A, the substrate 110 may include an unevenness structure provided on a surface thereof on which the first conductivity-type semiconductor layer 121 is formed and may contain sapphire, Si, SiC, MgAl₂O₄, MgO, LiAlO₂, LiGaO₂, GaN or the like.

The light-emitting structure 120 may be formed by sequentially growing the first conductivity-type semiconductor layer 121, the active layer 122, and the second conductivity-type semiconductor layer 123 on the substrate 110, using a process such as metal organic chemical vapor deposition (MOCVD), hydride vapor phase epitaxy (HVPE), molecular beam epitaxy (MBE), or the like. The first conductivity-type semiconductor layer 121 and the second conductivity-type semiconductor layer 123 may be an n-type semiconductor layer and a p-type semiconductor layer, respectively. In the light-emitting structure 120, positions of the first conductivity-type semiconductor layer 121 and the second conductivity-type semiconductor layer 123 may be changed, and the second conductivity-type semiconductor layer 123 may be first formed on the substrate 110.

Referring to FIG. 9B, a portion of the light-emitting structure 120 may be etched to expose at least a portion of the first conductivity-type semiconductor layer 121. The light-emitting structure 120 may be divided into the first region R1 and the second region R2 enclosing the first region R1, and the first insulating layer 161 may be formed in a region of the light-emitting structure 120 to which the portion of the first conductivity-type semiconductor layer 121 is exposed. A portion of the first insulating layer 161 may be removed to partially expose the first conductivity-type semiconductor layer 121 and the second conductivity-type semiconductor layer 123.

As illustrated in FIG. 9B, in a process of etching a portion of the light-emitting structure 120 to expose at least a portion of the first conductivity-type semiconductor layer 121, the groove 120A may be formed by etching the portion of the light-emitting structure 120 adjacent to the edge of the substrate 110. Although the example embodiments illustrates a case in which the groove 120A has a depth to which the groove 120A partially penetrates through the first conductivity-type semiconductor layer 121, the groove 120A is not limited to having such a form. The first insulating layer 161 may be provided on the groove 120A. Here, in the case that the first insulating layer 161 contains SiN, the first insulating layer 161 may perform the same functions as those of the hydrophobic insulating layer 480 illustrated in FIG. 6.

Referring to FIG. 9B, the depth of the groove 120A may be identical to the depth of the etched region present within the first region R1. That is, the bottom surface of the interior portion of the groove 120A may form a coplanar surface with a bottom surface of the etched region present in the first region R1. Such characteristics may be derived because the etched region and the mesa region and the groove 120A are formed through a single process, and the depth of the groove 120A may be variously selected according to variations in process conditions.

Then, referring to FIG. 9C, the first contact electrode 135 and the second contact electrode 145 may be formed in the region which the first insulating layer 161 is removed. The second contact electrode 145 may include the reflective metal layer 143 and the coating metal layer 144. As illustrated in FIG. 3, the first contact electrode 135 may have a plurality of pad portions and finger portions extended from the plurality of pad portions.

Referring to FIG. 9D, the second insulating layer 162 may be formed to entirely cover the light-emitting structure 120. The second insulating layer 162 disposed on the first contact electrode 135 and the second contact electrode 145 may be selectively removed, and the first metal layer 151 and the second metal layer 152 may be formed on the second insulating layer 162. The first metal layer 151 may be electrically connected to the first contact electrode 135 in the first opening 161′ and the second metal layer 152 may be electrically connected to the second contact electrode 145 in the second opening 162′.

Referring to FIG. 9E, the cover layer 170 may be formed on the first and second metal layers 151 and 152, and the first and second electrodes 130 and 140 may be provided on regions of the first and second metal layers 151 and 152 from which the cover layer 170 is removed. The first and second electrodes 130 and 140 may be electrically connected to the first and second metal layers 151 and 152, respectively. A portion of the cover layer 170 may be extended to the interior portion of the groove 120A. The cover layer 170 may contain an electrically insulating material, for example, SiO₂, SiN, SiOₓN_{y}, TiO₂, Si₃N₄, Al₂O₃, TiN, AIN, ZrO₂, TiAlN, TiSiN and the like. In particular, in the case that the cover layer 170 contains SiN or ZrO₂, the cover layer 170 may perform the same functions as those of the hydrophobic insulating layer 480 illustrated in FIG. 6.

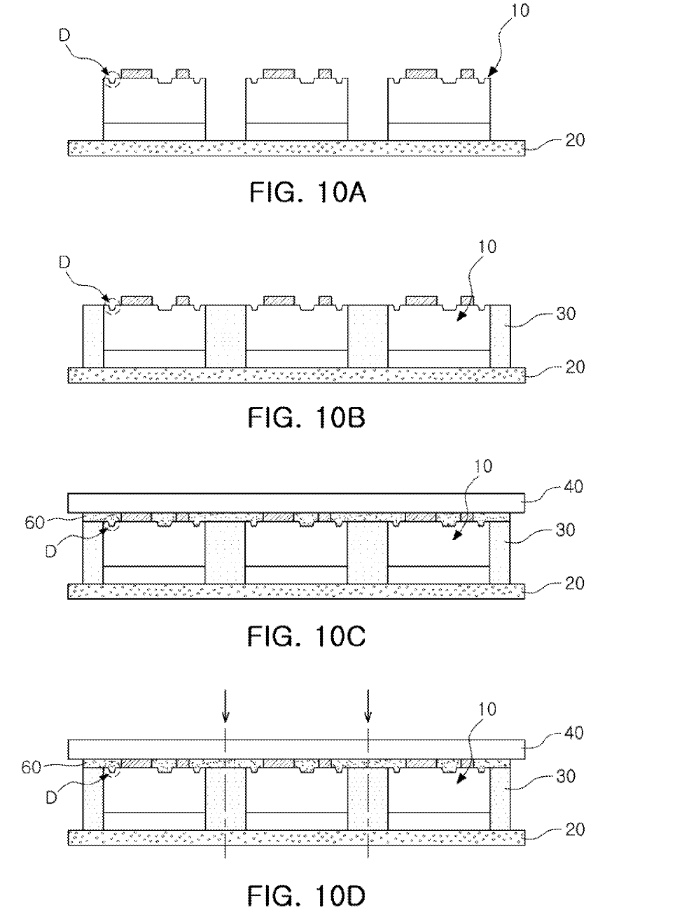

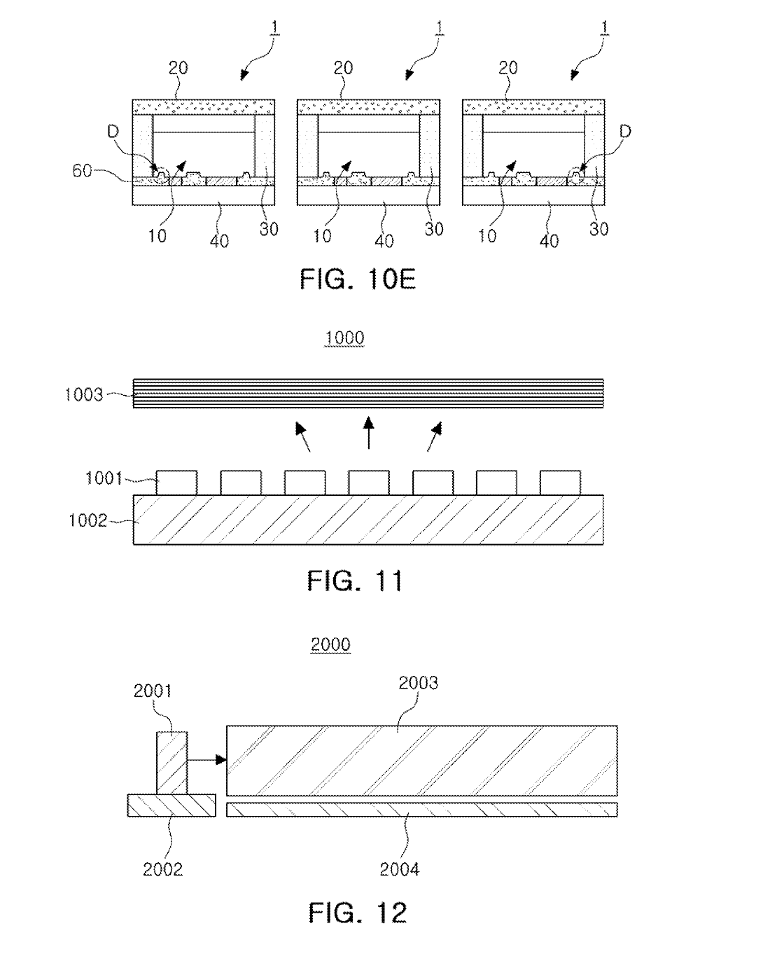

FIGS. 10A through 10E are views illustrating a method of manufacturing a semiconductor light-emitting device package according to example embodiments of the present inventive concepts.

Referring to FIG. 10A, the semiconductor light-emitting devices 10 may be disposed on the wavelength conversion film 20. The wavelength conversion film 20 may contain a wavelength conversion material. By way of example, the wavelength conversion film 20 may be manufactured by curing an encapsulant containing fluorescent substances. Each of the semiconductor light-emitting devices 10 may include a substrate, a light-emitting structure disposed on the substrate, first and second electrodes electrically connected to first and second conductivity-type semiconductor layers of the light-emitting structure, and the like.

In addition, as illustrated in FIG. 10A, each semiconductor light-emitting device 10 may include the groove D. The groove D may be disposed to be adjacent to a side edge of the semiconductor light-emitting device 10. Although FIG. 10A illustrates a case in which the groove D has a width narrowed in a depth direction, the width of the groove D may be increased in the depth direction or may not be substantially changed.

Then, referring to FIG. 10B, the reflective wall 30 may be formed on side surfaces of the semiconductor light-emitting devices 10. The reflective wall 30 may be formed to enclose the side surfaces of the semiconductor light-emitting devices 10 and may be formed by injecting a white molding composite material containing a filler into a space between the semiconductor light-emitting devices 10 disposed on the wavelength conversion film 20, using a dispenser and the like and then, curing the material. The filler may contain one or more materials selected from a group consisting of SiO₂, TiO₂, Al₂O₃ and the like, and may have nano-sized particles contained in the white molding composite material. The white molding composite material may contain a thermosetting resin or silicon resin having high heat resistance properties, or may contain a thermoplastic resin to which a white pigment and a filler, a curing agent, a releasing agent, an antioxidant agent, adhesion improving agent or the like may be added.

When the white molding composite material containing the filler is injected using the dispenser in order to form the reflective wall 30, in the case that an injection amount of the white molding composite material is not appropriately adjusted, a portion of the white molding composite material may be introduced to the semiconductor light-emitting device 10. In example embodiments of the present inventive concepts, the groove D may be formed in a partial region of the semiconductor light-emitting device 10 adjacent to the reflective wall 30 to prevent a phenomenon in which the white molding composite material injected in an excessive amount is introduced into the inside of the semiconductor light-emitting device 10.

Referring to FIG. 10C, the circuit board 40 may be attached to the semiconductor light-emitting devices 10 and an encapsulant 60 may be filled in spaces between the circuit board 40 and the semiconductor light-emitting devices 10. At least a portion of conductive patterns present in the circuit board 40 may be electrically connected to the first and second electrodes of the semiconductor light-emitting devices 10 through solder bumps or the like. The encapsulant 60 may contain a thermosetting resin or the like and may also contain a filler, similarly to the reflective wall 30.

Then, referring to FIGS. 10D and 10E, a dicing process is performed on the reflective wall 30 disposed between the semiconductor light-emitting devices 10 to form the semiconductor light-emitting device package 1. Referring to FIG. 10E, the semiconductor light-emitting device package 1 may include the circuit board 40, the semiconductor light-emitting devices 10 mounted on the circuit board 40, the reflective wall 30 provided on the side surfaces of the semiconductor light-emitting devices 10, the wavelength conversion film 20 attached to upper surfaces of the semiconductor light-emitting devices 10, the encapsulant 60 filling the spaces between the semiconductor light-emitting devices 10 and the circuit board 40, and the like. Light generated due to the recombination of electrons and holes in the active layers of the semiconductor light-emitting devices 10 may be directly transferred to the wavelength conversion film 20 through the substrates of the semiconductor light-emitting devices 10 or may be reflected by the fillers contained in the reflective wall 30, the encapsulant 60, and the like to thereby be transferred to the wavelength conversion film 20.

FIGS. 11 and 12 are cross-sectional views each illustrating an example of applying the semiconductor light-emitting device package according to example embodiments of the present inventive concepts to a backlight unit.

Referring to FIG. 11, a backlight unit 1000 may include a light source 1001 mounted on a substrate 1002 and at least one optical sheet 1003 disposed thereabove. The light source 1001 may be a semiconductor light-emitting device package having the structure described with reference to FIGS. 9 and 10 or a structure similar thereto. In addition, the semiconductor light-emitting device may be directly mounted on the substrate 1002 (the so-called chip-on-board (COB) mounting manner) to be used.

The light source 1001 in the backlight unit 1000 of FIG. 11 emits light toward a liquid crystal display (LCD) device disposed thereabove. On the other hand, a light source 2001 mounted on a substrate 2002 in a backlight unit 2000 according to example embodiments illustrated in FIG. 12 emits light laterally, and the emitted light is incident to a light guide plate 2003 and may be converted into the form of a surface light source. The light, having passed through the light guide plate 2003, may be emitted upwardly and a reflective layer 2004 may be formed below a bottom surface of the light guide plate 2003 in order to improve light extraction efficiency.

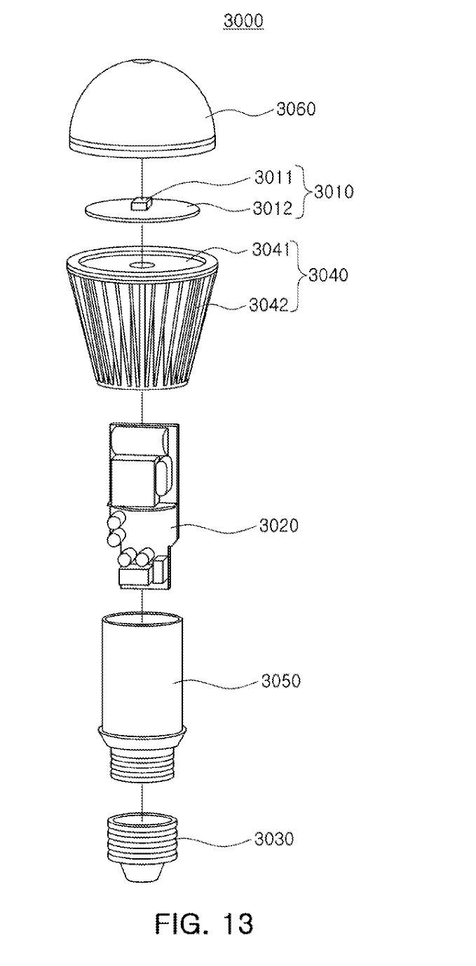

FIG. 13 is a view illustrating an example of applying the semiconductor light-emitting device package according to example embodiments of the present inventive concepts to a lighting device.

Referring to FIG. 13, a lighting device 3000 may be a bulb-type lamp, and includes a light-emitting module 3010, a driving unit 3020 and an external connector unit 3030. In addition, exterior structures such as an external housing 3040, an internal housing 3050, a cover unit 3060 and the like may be additionally included.

The light-emitting module 3010 may include a semiconductor light-emitting device 3011 having a structure the same as or similar to that of the semiconductor light-emitting device 1 of FIG. 1 and a circuit board 3012 having the semiconductor light-emitting device 3011 mounted thereon. Example embodiments illustrate the case in which a single semiconductor light-emitting device 3011 is mounted on the circuit board 3012; however, if necessary, a plurality of semiconductor light-emitting devices 3011 may be mounted thereon. In addition, the semiconductor light-emitting device 3011 may not be directly mounted on the circuit board 3012 and may be fabricated in the form of a package and subsequently, be mounted.

The external housing 3040 may serve as a heat radiating part, and include a heat sink plate 3041 in direct contact with the light-emitting module 3010 to improve the dissipation of heat and heat radiating fins 3042 covering a lateral surface of the external housing 3040. The cover unit 3060 may be disposed above the light-emitting module 3010 and may have a convex lens shape. The driving unit 3020 may be disposed inside the internal housing 3050 and may be connected to the external connector unit 3030 such as a socket structure to receive power from an external power source. In addition, the driving unit 3020 may convert the received power into a current source appropriate for driving the semiconductor light-emitting device 3011 of the light-emitting module 3010 and supply the converted current source thereto. For example, the driving unit 3020 may be configured of an AC-DC converter, a rectifying circuit part, or the like. Although not illustrated, the lighting device 3000 may further include a communications module.

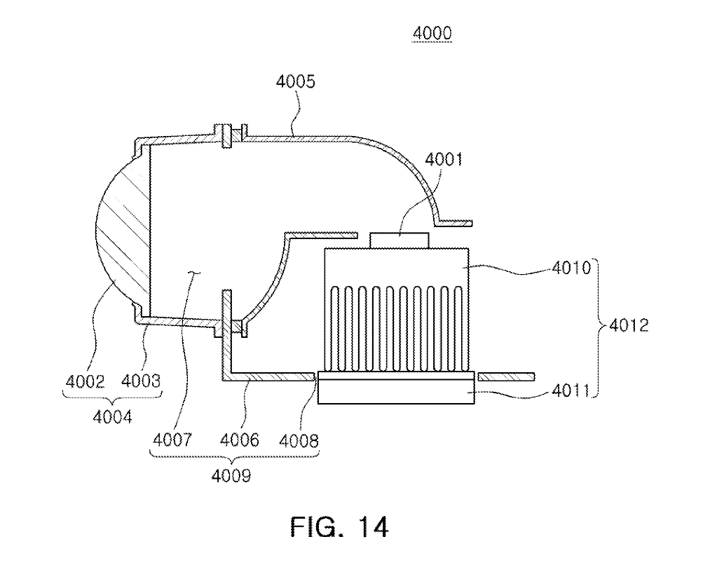

FIG. 14 is a view illustrating an example of applying the semiconductor light-emitting device package according to example embodiments of the present disclosure to a headlamp.

Referring to FIG. 14, a headlamp 4000 used as a vehicle lighting element or the like may include a light source 4001, a reflective unit 4005 and a lens cover unit 4004, the lens cover unit 4004 including a hollow guide part 4003 and a lens 4002. The light source 4001 may include the semiconductor light-emitting device or a package including the semiconductor light-emitting device as described above.

The headlamp 4000 may further include a heat radiating unit 4012 dissipating heat generated by the light source 4001 outwardly. The heat radiating unit 4012 may include a heat sink 4010 and a cooling fan 4011 in order to effectively dissipate heat. In addition, the headlamp 4000 may further include a housing 4009 allowing the heat radiating unit 4012 and the reflective unit 4005 to be fixed thereto and supported thereby. The housing 4009 may include a body part 4006 and a central hole 4008 to which the heat radiating unit 4012 is coupled, the central hole 4008 being formed in one surface of the housing 4009.

The other surface of the housing 4009 integrally connected to and bent in a direction perpendicular to the one surface of the housing 4009 may be provided with a forward hole 4007 such that the reflective unit 4005 may be disposed above the light source 4001. Accordingly, a forward side may be opened by the reflective unit 4005 and the reflective unit 4005 may be fixed to the housing 4009 such that the opened forward side corresponds to the forward hole 4007, whereby light reflected by the reflective unit 4005 may pass through the forward hole 4007 to thereby be emitted outwardly.

As set forth above, according to various example embodiments of the present inventive concepts, a groove, a hydrophobic insulating layer or the like may be formed in a partial region of a semiconductor light-emitting device adjacent to a reflective wall. Thus, a phenomenon a liquid having fluidity and applied to a circumferential portion of the semiconductor light-emitting device to form the reflective wall is introduced to the semiconductor light-emitting device may be prevented, whereby defects such as a bleeding phenomenon may be prevented.

While example embodiments have been shown and described above, it will be apparent to those skilled in the art that modifications and variations could be made without departing from the scope of the disclosure as defined by the appended claims.

What is claimed is:

1. A semiconductor light-emitting device comprising:
at least one light-emitting structure including a first conductivity-type semiconductor layer, an active layer, and a second conductivity-type semiconductor layer sequentially stacked on a substrate, the at least one light-emitting structure having a first region and a second region delimiting the first region,
wherein the light-emitting device includes a groove in the second region, and
the groove is adjacent to an edge of the substrate and extends parallel to the edge of the substrate.

2. The semiconductor light-emitting device of claim 1, wherein the at least one light-emitting structure includes a mesa region, and an etched region having a thickness smaller than a thickness of the mesa region, and
the semiconductor light-emitting device further includes a first contact electrode on the first conductivity-type semiconductor layer in the etched region, and a second contact electrode on the second conductivity-type semiconductor layer in the mesa region.

3. The semiconductor light-emitting device of claim 2, wherein the first contact electrode extends in a first direction, and
the groove extends in a second direction intersecting the first direction, the groove being in the second region so as to be adjacent to the first contact electrode.

4. The semiconductor light-emitting device of claim 2, wherein a depth of the groove is substantially the same as a depth of the etched region.

5. The semiconductor light-emitting device of claim 2, further comprising:
a first insulating layer on the at least one light-emitting structure, the first insulating layer having a first opening exposing at least a portion of the first conductivity-type semiconductor layer and the second conductivity-type semiconductor layer; and
a second insulating layer on the first insulating layer, the second insulating layer exposing at least a portion of the first contact electrode and the second contact electrode.

6. The semiconductor light-emitting device of claim 5, wherein at least one of the first insulating layer and the second insulating layer is on the groove.

7. The semiconductor light-emitting device of claim 2, further comprising:
a first metal layer electrically connected to the first contact electrode; and
a second metal layer electrically connected to the second contact electrode.

8. The semiconductor light-emitting device of claim 1, wherein a width of the groove narrows towards the substrate.

9. The semiconductor light-emitting device of claim 1, wherein the groove has a width increasing towards the substrate.

10. The semiconductor light-emitting device of claim 1, further comprising:
a hydrophobic insulating layer on at least a portion of the second region.

11. The semiconductor light-emitting device of claim 10, wherein the hydrophobic insulating layer contains at least one of ZrO₂ and SiN.

12. A semiconductor light-emitting device package, comprising:
a semiconductor light-emitting device including a first conductivity-type semiconductor layer, an active layer, and a second conductivity-type semiconductor layer sequentially stacked on a first surface of a substrate, the semiconductor light-emitting device having a first region and a second region having a thickness smaller than a thickness of the first region;
a wavelength conversion film attached to a second surface of the substrate opposing the first surface, the wavelength conversion film containing a wavelength conversion material; and
a reflective wall delimiting side surfaces of the semiconductor light-emitting device,
wherein the semiconductor light-emitting device has a groove adjacent to the reflective wall.

13. The semiconductor light-emitting device package of claim 12, further comprising:
a hydrophobic insulating layer on at least a portion of the second region.

14. The semiconductor light-emitting device package of claim 12, wherein the reflective wall contains at least one of TiO₂, SiO₂ and Al₂O₂.

15. The semiconductor light-emitting device package of claim 12, further comprising:
a package substrate on which the semiconductor light-emitting device is mounted, and
an encapsulant between the package substrate, the semiconductor light-emitting device, and the reflective wall.

16. A semiconductor light-emitting device, comprising:
a substrate including a first region, and a second region along a periphery of the first region; and
at least one light-emitting structure including a semiconductor layer,
wherein the semiconductor layer extends over the first region and at least a portion of the second region, and
the semiconductor layer has a first groove over the at least a portion of the second region.

17. The semiconductor light-emitting device of claim 16, wherein a first sidewall and a second sidewall of the semiconductor layer form sides of the first groove, and
the first sidewall slopes away from the second sidewall towards a bottom surface of the first groove.

18. The semiconductor light-emitting device of claim 16, wherein the semiconductor layer includes a second groove over the first region, and
bottom surfaces of the first and second grooves are at a same level.

19. The semiconductor light-emitting device of claim 16, further comprising:
a hydrophobic insulating layer covering at least a portion of the semiconductor layer extending over the at least a portion of the second region.

20. The semiconductor light-emitting device of claim 19, wherein the semiconductor layer includes a second groove over the first region,
a bottom surface of the second groove is at a same level as a first bottom surface of the first groove, and
the first groove includes a second bottom surface lower than the first bottom surface.
